(19) United States
(12) Patent Application Publication
(10) Pub. No.: US 2001/0031524 A1
(43) Pub. Date: Oct. 18, 2001

(54) Nonvolatile memory device and manufacturing method therefor

(75) Inventors: Jong-Han Kim, Seongnam-city (KR); Jeong-Hyuk Choi, Suwon-city (KR)

Correspondence Address: MARGER JOHNSON & MCCOLLOM PC, 1030 SW MORRISON STREET, PORTLAND, OR, 97205, US

(73) Assignee: Samsung Electronics Co., Ltd., Suwon-City (KR)

(21) Appl. No.: 09/882,153

(22) Filed: Jun. 14, 2001

Related U.S. Application Data
(62) Division of application No. 09/352,449, filed on Jul. 13, 1999.
(60) Provisional application No. 60/092,555, filed on Jul. 13, 1998.

(51) Int. Cl. H01L 21/8238; H01L 21/336

(52) U.S. Cl. 438/201; 438/211; 438/257; 438/266

(57) ABSTRACT

A nonvolatile memory device and a manufacturing method therefor are provided. The nonvolatile memory device includes source pad lines connecting source regions of neighboring cells, parallel to word lines. Thus, the number of common source lines necessary for the overall cell array area can be reduced. Also, the distance between a word line and a contact hole is minimized by providing self-aligned bit line contact holes, thereby minimizing the size of a cell array area.

This application is a divisional of U.S. patent application Ser. No. 09/352,449, filed on Jul. 13, 1999, now pending, which is herein Incorporated by reference in its entirety.

### BACKGROUND OF THE INVENTION

1. Field of the Invention

The present invention relates to a semiconductor memory device and a manufacturing method therefor and, more particularly, to a highly integrated nonvolatile memory device and a manufacturing method therefor.

2. Description of the Related Art

In order to build a highly integrated nonvolatile memory device, it is necessary to reduce the dimension of the features of the device. A self-aligned source etching process has been used to reduce the size of a memory cell array. The examples of the self-aligned source etching process are disclosed in the U.S. Pat. Nos. 5,120,671 and 5,470,773.

FIG. 1 is a layout diagram of a nonvolatile memory device formed according to the above two patents, e.g., a flash memory device, and FIG. 2 is a cross-sectional view taken along line II-II′ shown in FIG. 1.

Reference numeral 10 represents an active region pattern; reference numeral 20 represents a floating gate pattern; reference numeral 30 represents a control gate pattern; reference numeral 50 represents a bit line contact pattern; reference numeral 60 represents a bit line pattern; reference numeral 70 represents a common source line contact pattern; and reference numeral 80 represents a common source line pattern.

In the above patents, a source line diffusion layer, necessary for connecting source regions of neighboring cells in a word line direction, is not formed within the active region. A field oxide is etched and a source line diffusion layer is formed thereunder to connect source regions of neighboring cells in a word line direction. Thus, since an insulation distance between the word line and the source line diffusion layer need not be maintained, the size of a memory cell array can be reduced.

The method disclosed in those two patents will now be described briefly. First, a stacked gate is formed in an active region of a semiconductor substrate 5 defined by a field oxide 12. The stacked gate is formed by depositing a tunnel oxide 15, a floating gate 20, an insulating layer 25 and a control gate 30. An oxide spacer 32 is formed on the side walls of the stacked gate. Subsequently, a mask exposing a source region and the adjacent field oxide 12 in a word line direction is formed and then the field oxide 12 is removed by self-aligned source etching. N⁺-type ions are then implanted into the exposed substrate to form a source line diffusion layer 41 parallel to the word line (30 of FIG. 1). The oxide spacer 32 may be formed after the self-aligned source etching. Ions are implanted into the source and drain regions to complete a drain region 42 and a source region 43. An insulating layer 47 is deposited and then a contact hole 50 exposing the drain region 42 and a contact hole 70 exposing the source region 46 are formed by a photolithography process. Next, a metal layer is deposited over the entire surface of the resultant structure and then patterned to complete a bit line 60 and a common source line 80.

According to the method, during the self-aligned source etching, not only the field oxide 12 but the active region on which the source region 43 is to be formed is etched. In other words, the silicon substrate of the active region is over-etched to a thickness of 300 Å or more, which causes etching damage to the source region. Such damage reduces a charge retention capability. The etching damage may be cured by annealing. However, the annealing must be performed at a high temperature in the range of 900-1000° C., causing other problems.

In the conventional nonvolatile memory device, since the common source line 80 and the source region 43 of each cell are connected through the source line diffusion layer 41, the reduced cell size according to high integration reduces the area of the source line diffusion layer, increasing source resistance. If the source resistance increases, a discharge speed during the operation of the cell is lowered, which degrades the performance of the cell. To avoid this problem, the number of source regions 43 connected to a common source line 80 must be reduced. In other words, more common source lines must be formed in a cell array. An increase in the number of common source lines 80 undesirably increases the area of the cell array.

Also, according to the above-mentioned patents, considering a processing margin of a photolithography process for forming the bit line contact hole 50, a sufficient distance L must be secured between the stacked gate and the bit line contact hole 50. Thus, enhancing an integration level in a bit line direction is limited.

### SUMMARY OF THE INVENTION

To solve the above problems, it is an objective of the present invention to provide a highly integrated nonvolatile memory device by providing a new source line and a self-aligned contact.

It is another objective of the present invention to provide a method suitable for manufacturing a highly integrated nonvolatile memory device having a new source line and a self-aligned contact.

Accordingly, there is provided a nonvolatile memory device comprising: a plurality of active regions formed on a semiconductor substrate and defined by a plurality of isolation areas extending in parallel; a plurality of stacked gates perpendicular to the active regions, each of the stacked gates comprising a first gate and a second gate, the first gates being insulated from the semiconductor substrate and formed on the active regions and some parts of isolation areas and the second gate being insulated from the first gates and successively formed on the first gates and isolation areas; a plurality of source regions formed in the active regions between the stacked gates; a plurality of first contact holes self-aligned with the plurality of stacked gates, formed in a first interlevel dielectric layer on the semiconductor substrate, and exposing the source regions and the isolation areas between the stacked gates parallel to the stacked gates; a plurality of source pad lines formed in the first contact holes and connecting the exposed source regions, parallel to the stacked gates; and a source line connected to the source pad lines, and arranged parallel with the active regions.

Also, the nonvolatile memory device further comprises: a plurality of drain regions formed in the active regions between the stacked gates; a plurality of second contact holes self-aligned with the plurality of stacked gates, formed in a first interlevel dielectric layer on the semiconductor substrate, and exposing the drain regions; a plurality of plugs formed in the second contact holes and connecting the drain regions; and a plurality of bit lines connected to the plurality of plugs arranged parallel with the isolation areas, and parallel to the active regions.

In the present invention, an etching stopper is preferably formed on the top and side walls of the stacked states. Also, the plugs formed in the first contact holes are preferably formed of a metal having a lower resistance than the resistance of an impurity diffusion layer. Further, the plugs and the source pad lines have top surfaces that are substantially coplanar.

To achieve the second objective, there is provided a method for manufacturing a nonvolatile memory device, comprising the steps of: (a) providing a semiconductor substrate; (b) defining a plurality of active regions by forming a plurality of isolation areas extending in parallel on a semiconductor substrate; (c) forming a plurality of stacked gates comprised of a plurality of first gates insulated from the semiconductor substrate and formed on the active regions and some parts of isolation areas and a plurality of second gates insulated from the first gates, formed on the first gates and isolation areas and perpendicular to the plurality of active regions; (d) forming a plurality of source regions and a plurality of drain regions by implanting impurities into the active regions between the stacked gates; (e) forming a first interlevel dielectric layer on the resultant structure where the plurality of source and drain regions are formed; (f) forming a plurality of first contact holes that expose the source regions and isolation areas between the stacked gates, parallel to the stacked gates, by patterning the first interlevel dielectric layer; and (g) forming a plurality of source pad lines connecting the source regions, parallel to the stacked gates, in the first contact holes.

Subsequently, after step (g), there are further provided the steps of (h) forming a second interlevel dielectric layer on the resultant structure where the plurality of source pad lines are formed, (i) forming a plurality of via holes exposing the plurality of pad lines, by patterning the second interlevel dielectric layer, and (j) filling the via holes, connecting the source pad lines and forming a source line parallel to the active region.

In the present invention, step (f) is performed by forming the plurality of first contact holes and a plurality of second contact holes exposing the drain regions between the plurality of stacked gates, using a single mask, and step (g) is performed by forming the source pad lines and plugs in the second contact holes.

Particularly, before step (e), there is further provided the step of forming an etching stopper layer on the top and side walls of the stacked gates, and wherein step (f) is performed by forming the first and second contact holes self-aligned with the stacked gates and the etching stopper layer.

Also, after step (f), there is further provided the step of implanting plug ions into the source and drain regions exposed by the first and second contact holes, using the single mask.

According to the present invention, since source regions of neighboring cells are connected to a source pad line, the number of common source lines required in the overall cell array area can be reduced. Also, a self-aligned bit line contact hole is provided to reduce the distance between a stacked gate and the bit line contact hole, thereby minimizing the size of a cell array area.

### BRIEF DESCRIPTION OF THE DRAWINGS

The above objectives and advantages of the present invention will become more apparent by describing in detail a preferred embodiment thereof with reference to the attached drawings in which:

FIG. 1 is a layout diagram of part of a cell array of a conventional flash memory device;

FIG. 2 is a cross-sectional view taken along line II-II′ of FIG. 1;

FIG. 3 is a layout diagram of part of a cell array of a flash memory device according to an embodiment of the present invention;

FIG. 4 is an equivalent circuit diagram of the flash memory device shown in FIG. 3;

FIG. 5 is a cross-sectional view taken along line V-V′ of FIG. 3;

FIGS. 6 through 13 are cross-sectional views of structures created in the course of manufacturing the flash memory device shown in FIG. 3, taken along line V-V′; and

FIGS. 14 and 15 are cross-sectional views of structures created in an another course of manufacturing a flash memory device shown in FIG. 3, taken along line V-V′.

### DESCRIPTION OF THE PREFERRED EMBODIMENTS

Hereinbelow, the present invention will be described in detail by describing preferred embodiments of the present invention with reference to the accompanying drawings. However, the present invention is not limited to the following embodiments and may be implemented in various forms. These embodiments are provided only to completely disclose the invention and fully convey the concepts of the invention to those who have ordinary skills in the art. Throughout the drawings, components of various devices, the positional relationships therebetween and the thicknesses of various films and areas are emphasized for clarity. In the drawings, the same elements are designated by the same numbers throughout.

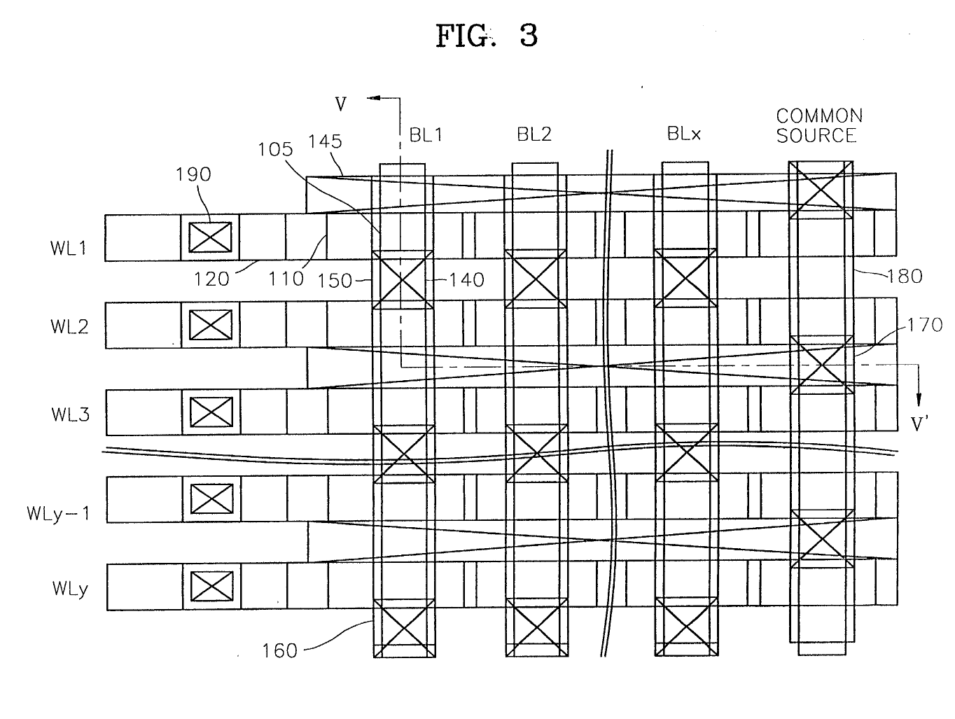

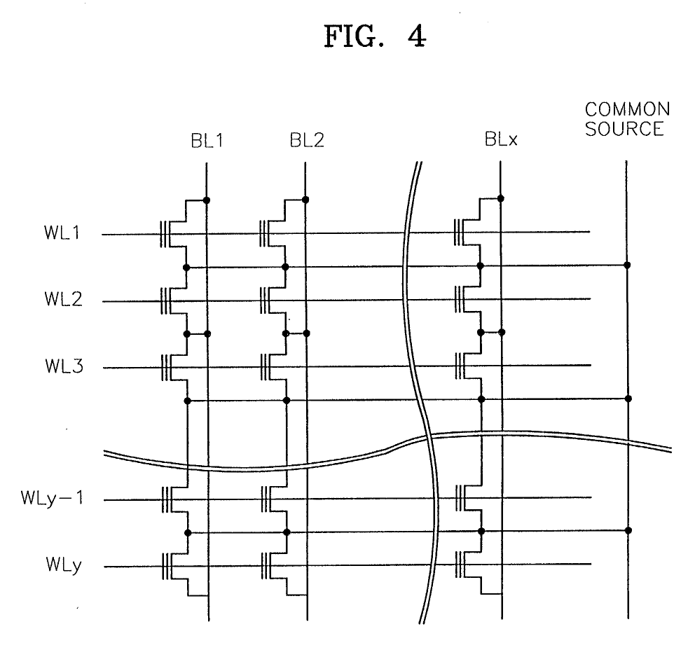

FIG. 3 is a layout diagram of part of a cell array of a flash memory device according to an embodiment of the present invention, and FIG. 4 is an equivalent circuit diagram of the flash memory device shown in FIG. 3.

Reference numeral 105 represents an active region pattern; reference numeral 110 represents a floating gate pattern; reference numeral 120 represents a control gate pattern functioning as a word line; reference numeral 140 represents a bit line contact hole pattern; reference numeral 145 represents a source pad line contact hole pattern; reference numeral 150 represents a bit line via hole; reference numeral 160 represents a bit line pattern, reference numeral 170 represents a source line via hole; reference numeral 180 represents a common source line pattern; and reference numeral 190 represents a word line contact hole pattern.

FIG. 5 is a cross-sectional view taken along line V-V′ of FIG. 3.

A flash memory device according to the present invention will be described with reference to FIGS. 3, 4 and 5. The flash memory device according to the present invention can store and erase data electrically. It includes a plurality (X) of active regions 105 defined by a plurality of isolation regions 102 extending in parallel in one direction and formed on a semiconductor substrate 100. A plurality (X×y) of stacked gates comprised of a plurality (X×y) of floating gates 110 and a plurality (y) of control gates 120 are provided in the active regions 105. The floating gates 110 are formed on the active regions and some parts of isolation regions 102. The control gates 120 function as word lines and extend across the active regions 105. A unit cell is defined at an area where an active region 105 and a control gate 120 intersect. The floating gates 110 are formed of polysilicon and the control gates 120 10 may be formed of a single layer of polysilicon or a multi-layer composed of a polysilicon layer 120A and a silicide layer 120B. The floating gates 110 are insulated from the active regions of the semiconductor substrate 100 by an interposed tunnel oxide 106. The control gates 120 are insulated from the floating gates 110 by an interposed insulating layer 115, e.g., a laminated insulating layer of oxide and nitride (ONO) or a metal oxide material having a high dielectric constant.

Impurity regions, i.e., source regions 135 and drain regions 132, are formed in the active regions 105 between the stacked gates 110 and 120. First interlevel dielectric layer patterns 136P are deposited on the stacked gates 110 and 120.

The source regions 135 and the drain regions 132 are exposed by first contact holes 145 and second contact holes 140, respectively.

The first contact holes 145, i.e., source pad line contact holes, are formed parallel to the word lines 120 between the stacked gates to expose the source regions 135 and the isolation regions 102 adjacent to the source regions 135 in a direction of the word line 120. The second contact holes 140, i.e., drain contact holes, expose the plurality of drain regions 132 between the stacked gates. At this time, the first and second contact holes 145 and 140 are preferably formed in self-alignment with a nitride layer 122 at the side walls and on top of the stacked gates.

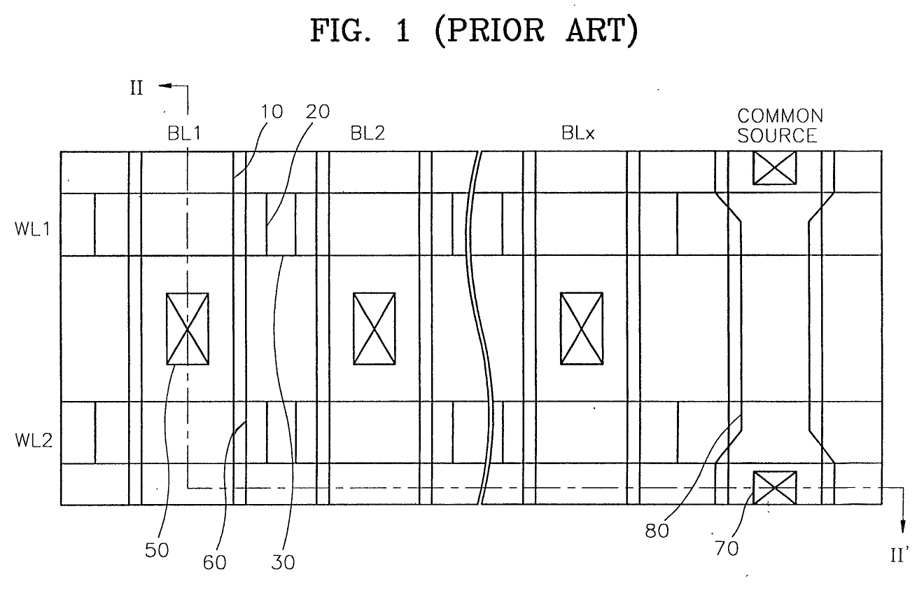

Source pad lines 145′ connecting source regions of neighboring cells in the word line direction, and bit line plugs 140′, are formed in the first contact holes 145 and the second contact holes 140, respectively. The source pad lines 145′ and the bit line plugs 140′ are preferably formed of a metal having a resistance lower than the source line diffusion layer (41 of FIG. 1), e.g., tungsten, aluminum or copper.

The plurality of source pad lines 145′ parallel to the plurality of word lines 120 are connected to common source lines 180 through via holes 170 formed in a second interlevel dielectric layer 147 to expose the source pad lines 145′. The common source lines 180 are arranged parallel to the active region 102.

The plurality of bit line plugs 140′ are connected to the bit lines 160 through via holes 150 formed in the second interlevel dielectric layer 147 to expose the bit line plugs 140′. The bit lines 160 are disposed parallel to the active regions 105 to be perpendicular to the word lines 120.

An etching barrier 146 is preferably deposited on the source pad lines 145′, the bit line plugs 140′ and the first interlevel dielectric layer pattern 136P. This is to prevent damage to the first interlevel dielectric layer patterns 136P in the course of forming the via holes 150 and 170.

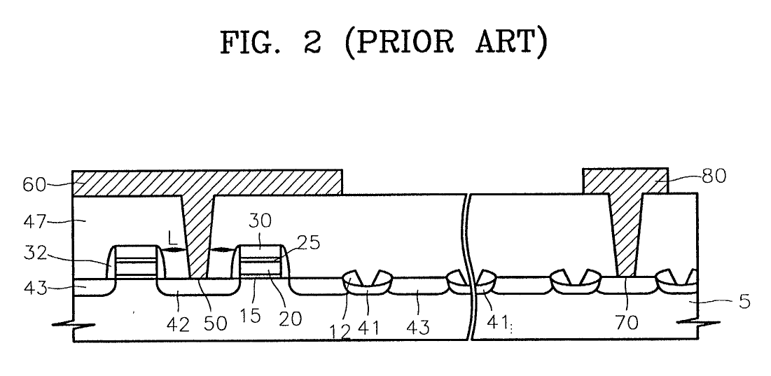

As described above, source regions of neighboring unit cells are connected to the source pad lines formed of a low resistance metallic material. Since the source pad lines are formed of a metal having a lower resistance than the conventional source line diffusion layer (41 of FIG. 2), it can connect more source regions than the conventional source line diffusion layers. Thus, unlike the conventional art in which one common source line must be provided for every 16 to 32 bit lines, the common source line of the present invention has to be provided only for every 32 bit lines or more. Thus, the cell array area can be reduced because the number of common source lines 180 to be arranged in a cell array area is reduced.

Also, in order to form the conventional source line diffusion layer (41 of FIG. 2), the field oxide 102 must be etched and it may damage the active region and reduce a charge retention capability. But in the present invention, since the source pad lines 145′ are formed in the self-aligned contact holes, self-aligned with the stacked gates, the problem of over-etching the active regions on which source regions are to be formed is fundamentally avoided, thereby improving device characteristics.

Also, since the bit line contacts are self-aligned, it is not necessary to maintain a distance between the word line 120 and contact hole 140 (“L” in the conventional art), thereby improving integration.

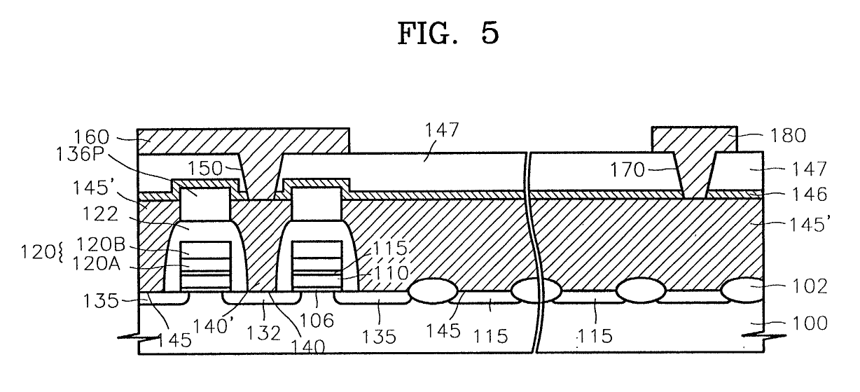

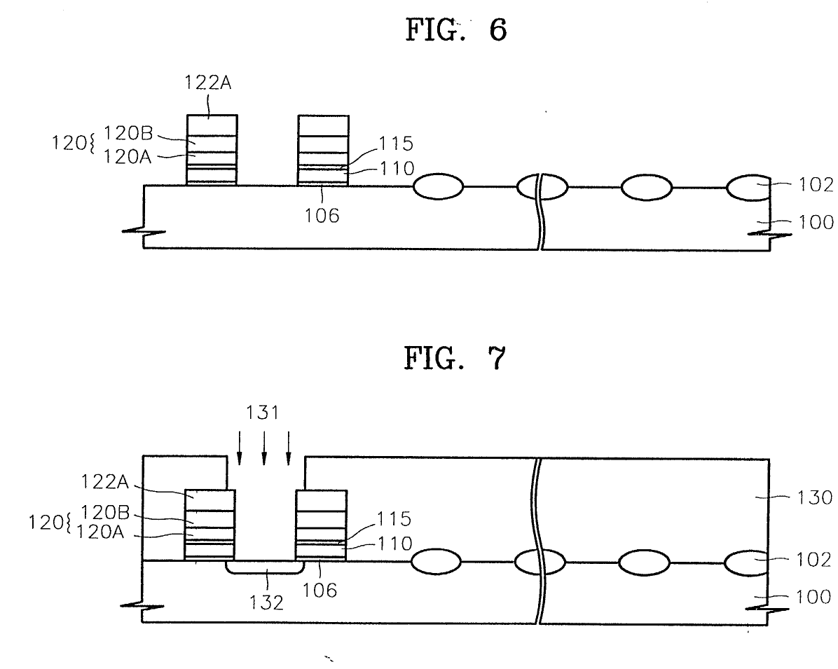

Hereinbelow, a method for manufacturing a cell array area of a flash memory device according to the present invention will be described with reference to FIGS. 6 through 13.

Referring to FIG. 6, an isolation region 102 is formed on a semiconductor substrate 100 to define an active region. Subsequently, a tunnel oxide 106, a floating gate 110, an insulating layer 115, a control gate 120 and an etching stopper layer 122A are formed on the active region to form stacked gates.

The control gate 120 may be formed of a single layer of polysilicon, but is preferably formed of a multi-layer composed of a polysilicon layer 120A and a silicide layer 120B to reduce the resistance of the control gate 120. The etching stopper 122A prevents the stacked gates from being exposed during a subsequent step of forming self-aligned contact holes. Thus, the etching stopper layer 122A is preferably formed of a material having a lower etching rate than the first interlevel dielectric layer (see 136 of FIG. 9), e.g., an oxide layer. For example, the etching stopper layer 122A may be formed of a nitride layer, a double layer formed of a nitride layer and an oxide layer, or an oxynitride layer, to a thickness of 2000-4000 Å.

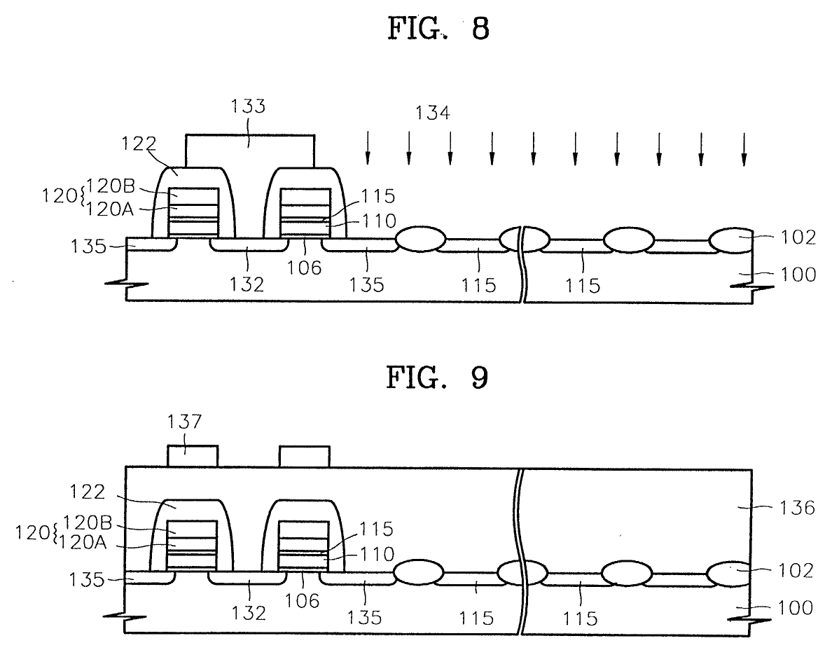

Next, as shown in FIGS. 7 and 8, a drain region 132 and a source region 135 are 10 formed in an active region of a semiconductor substrate 100. First, as shown in FIG. 7, a first mask pattern 130 exposing the active regions between stacked gates is formed on the semiconductor substrate 100 and then impurity ions 131 are implanted thereinto to form the drain region 132.

Subsequently, as shown in FIG. 8, an etching stopper spacer is formed on the side walls of the stacked gates, thereby completing an etching stopper 122. Like the etching stopper layer 122A, the etching stopper spacer prevents the stacked gates from being exposed during a subsequent step of forming self-aligned contact holes. Thus, the etching stopper spacer is preferably formed of the same material as that of the etching stopper layer 122A formed on top of the stacked gates, i.e., a material having a lower etching rate than the first interlevel dielectric layer (see 136 of FIG. 9). For example, a nitride layer, a double layer of a nitride layer and an oxide layer, or an oxynitride layer is deposited to a thickness of 500˜1000 Å and then etched back to form the spacer.

After completing the etching stopper 122, a second mask pattern 133 exposing the active region between the stacked gates is formed and then impurity ions 134 are ion-implanted thereinto, thereby forming the source region 135.

In this embodiment, ion implantation for forming the drain region 132 is performed before forming the spacer constituting the etching stopper 122, and ion implantation for forming the source region 135 is performed after forming the spacer. However, according to the structures of the source and drain regions, the order of forming the spacer, the drain region and the source region may be changed.

Then, as shown in FIG. 9, the first interlevel dielectric layer 136 is formed on the etching stopper 122, to sufficiently cover the stacked gates. The first interlevel dielectric layer 136 is formed by depositing a high temperature oxide and a BPSG layer to thicknesses of 500˜1000 Å and 4000˜6000 Å, respectively, and then reflowing the same at a temperature in the range of 850 to 900° C. for 10 to 20 minutes. A third mask pattern 137 defining a bit line contact portion and a source contact portion of the cell array is formed on the first interlevel dielectric layer 136.

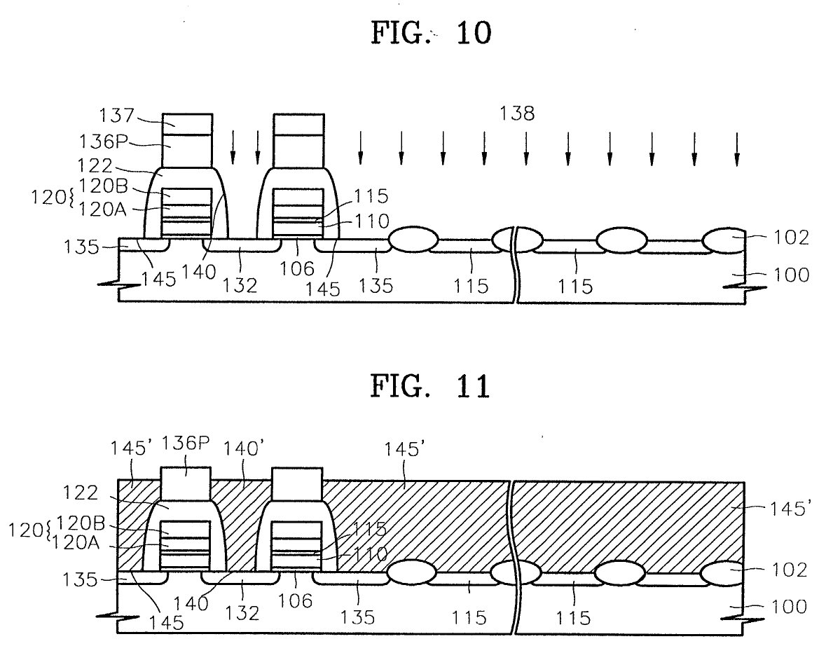

Referring to FIG. 10, the first interlevel dielectric layer 136 is anisotropically etched using the third mask pattern 137 as an etching mask, to thus form a bit line contact hole 140 and a source pad line contact hole 145 and leave a first interlevel dielectric layer pattern 136P on top of the stacked gates. Since a self-aligned contact process is allowed, in which alignment is performed by the stacked gates and the etching stopper 122 surrounding the stacked gates, the bit line contact hole 140 and the source pad line contact hole 145 can be easily formed by a reduced design rule. Thus, the size of the cell array can be reduced.

Next, plug-ion-implantation of arsenic or phosphorus is performed on the active region exposed by the bit line contact hole 140 and the source pad line contact hole 145, at a dose of 5×10^{13˜}1×10¹⁵ ions/cm², using the third mask pattern 137 as an ion implantation mask. The plug-ion-implantation reduces contact resistance by properly overlapping the bit line contact and source pad line contact with the impurity regions of the source and drain regions, in case when the bit line contact hole 140 and the source pad line contact hole 145 are misaligned to deviate from the drain and source regions 132 and 135.

In the present invention, since the bit line contact hole 140 and the source pad line contact hole 145 are formed by the self-aligned contact process, both the process for forming these contact holes 140 and 145 and also the ion implantation can be performed using a single mask pattern 137. Thus, the process is simpler than the conventional process.

Referring to FIG. 11, after removing the third mask pattern 137, a metal layer is deposited to fill the bit line contact hole 140 and the source pad line contact hole 145. Then, the metal layer is removed to remain only within the bit line contact hole 140 and the source pad line contact hole 145 by etch back or chemical mechanical polishing, forming a bit line plug 140′ and a source pad line 145′. Thus, the heights of the bit line plug 140′ and source pad line 145′ are the same so that their top surfaces are level with one another.

The metal layer is preferably formed of a low resistance metal, e.g., tungsten, aluminum or copper. Since source regions of neighboring cells are connected by forming the source pad line 145′ in such a manner, source resistance can be reduced. Thus, since fewer common source lines are arranged in the cell array area, the size of the cell array area can be reduced.

Referring to FIG. 12, an etching barrier 146 and a second interlevel dielectric layer 147 are sequentially formed on the entire surface the resultant structure shown in FIG. 11. Then, a fourth mask pattern 149 is formed defining via holes to expose the bit line plug 140′ and the source pad line 145′.

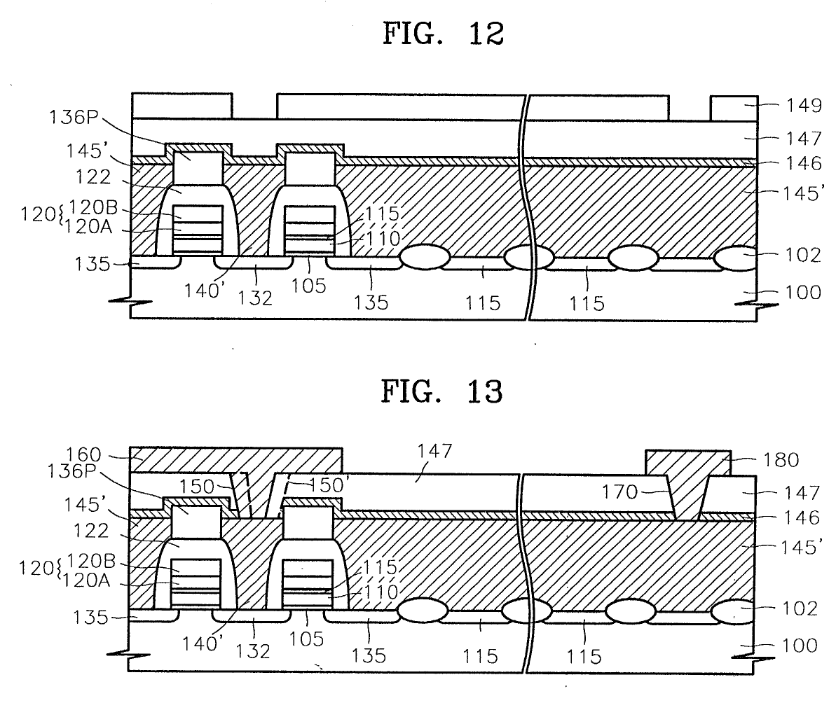

Referring to FIG. 13, the second interlevel dielectric layer 147 is etched using the fourth mask pattern 149 as an etching mask, to form via holes 150 and 170. Here, if misalignment occurs, to form a via hole 150′, the etching barrier 146 prevents the first interlevel dielectric layer pattern 136P from being etched.

Subsequently, a metal layer is formed on the via holes 150 and 170 and patterned, thereby completing the bit line 160 and the common source line 180.

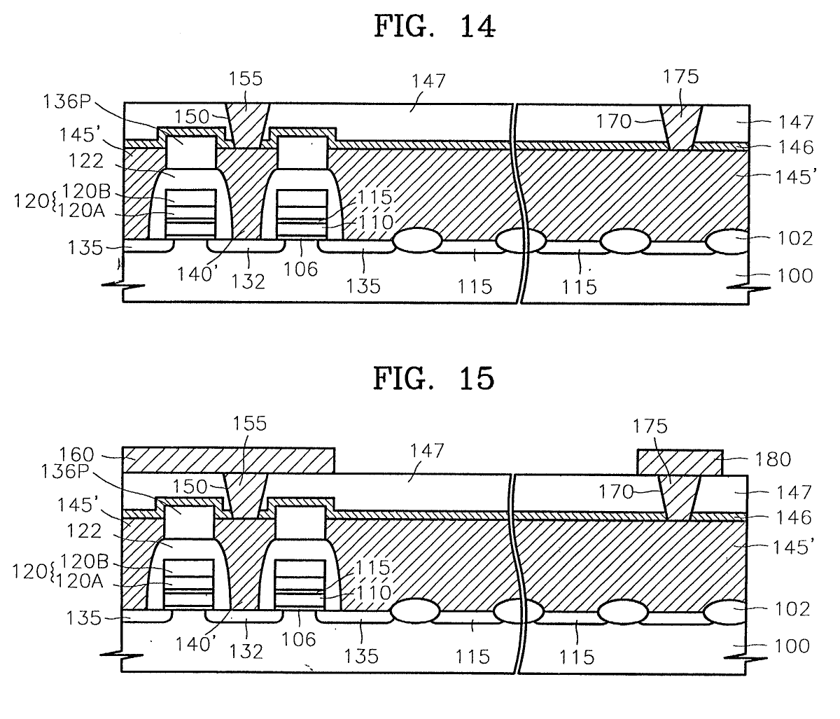

FIGS. 14 and 15 illustrate an another method for manufacturing a flash memory device of the present invention.

The second embodiment is different from the first embodiment in that a metal layer is deposited in the via holes 150 and 170 and then planarized by etch back or chemical mechanical polishing to form interlevel plugs 155 and 175, as shown in FIG. 14. Here, such planarization minimizes the step difference between a cell array area and a peripheral circuit area (not shown) and planarizes the second interlevel dielectric layer 147.

Next, as shown in FIG. 15, the bit line 160 and the common source line 180 connected to the interlevel plugs 155 and 175 are formed by a conventional manner.

As described above, in the flash memory device of the present invention, source regions of neighboring cells are connected by a source pad line formed of a low resistance metallic material. Since the source pad line is formed of a metal having a lower resistance than the conventional source diffusion layer, it can connect source regions of more cells than the source diffusion layer. Thus, the spacing of the common source lines can be increased to one every 32 bit lines or more, thereby reducing the overall area of the cell array region.

Also, since the source pad line of the present invention is formed within a self-aligned contact hole with stacked gates, a field oxide etching process is not necessary, unlike the conventional art, fundamentally preventing etching damage to the active region, and improving device characteristics.

Further, since the bit line contact is self-aligned, the distance between the word line and the bit line contact can be minimized, reducing the size of a cell array region.

According to the manufacturing method of the present invention, a mask pattern for forming the bit line contact hole and the source pad line contact hole is also used as an ion implantation mask, simplifying the manufacturing process.

What is claimed is:

1. A method for manufacturing a nonvolatile memory device, comprising:
(a) providing a semiconductor substrate;
(b) defining a plurality of active regions by forming a plurality of isolation areas extending in parallel on the semiconductor substrate;
(c) forming a plurality of stacked gates, each of said stacked gates comprising a floating gate and a control gate;
(d) forming a plurality of source regions and a plurality of drain regions between the stacked gates;
(e) forming a first interlevel dielectric layer on the plurality of source and drain regions;
(f) forming a plurality of first contact holes, said first contact holes exposing the source regions and isolation areas between the stacked gates, and a plurality of second contact holes, said second contact holes exposing the plurality of drain regions;
(g) implanting plug ions into the source and drain regions exposed by the first and second contact holes;
(h) forming a plurality of source pad lines connecting the source regions in the first contact holes, and a plurality of plugs connected to the drain regions in the second contact holes;
(i) forming a second interlevel dielectric layer on the source pad lines and the plugs;
(j) forming a plurality of via holes in the second interlevel dielectric layer, exposing the source pad lines and the plugs;
(k) filling the via holes with a conductive layer; and
(l) patterning the conductive layer in the step of forming a source line contacting the source pad lines and a plurality of bit lines contacting the plugs.

2. The method according to the claim 1, wherein the step (d) is performed by the steps of:
forming the drains regions in the active region;
forming an etching stopper layer on the top and sidewalls of the stacked gate; and
forming the source regions in the active region.

3. The method according to claim 1, further comprising, before step (e), the step of forming an etching stopper layer on the top and side walls of the stacked gates, wherein the first and second contact holes are formed in self-alignment with the stacked gates and the etching stopper layer.

4. The method according to claim 1, wherein step (1) is performed by:
removing the conductive layer, where it overlies the second interlevel dielectric layer, by a planarizing process, thereby forming interlevel plugs in the via holes and planarizing the second interlevel dielectric layer;
forming a second conductive layer on the interlevel plugs; and
patterning the second conductive layer to form the source line and the plurality of bit lines.
